(19) United States
(12) Patent Application Publication
(10) Pub. No.: US 2007/0114610 A1
(43) Pub. Date: May 24, 2007

(54) Semiconductor device and method of fabricating the same

(75) Inventor: Jeong Ho Park, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/599,218

(22) Filed: Nov. 13, 2006

(30) Foreign Application Priority Data
Nov. 18, 2005 (KR) 10-2005-0110784

(51) Int. Cl. H01L 27/12

(52) U.S. Cl. 257/353

(57) ABSTRACT

Disclosed are a semiconductor device and a method of fabricating the same. The semiconductor device includes an isolation layer on a semiconductor substrate, and an active area which protrudes from the isolation layer (and the substrate) and which has rounded edge portions; a gate insulating layer and a gate electrode on the active area; and source/drain impurity areas in the active area adjacent to sides of the gate electrode.

### BACKGROUND OF THE INVENTION

1. Field of the Invention

The present invention relates to a semiconductor device and a method of fabricating the same.

2. Description of the Related Art

Recently, as semiconductor devices have become highly integrated, the size of transistors is gradually scaled down, but limitations still remain in reducing the junction depth of the source/drain terminals.

That is, as the conventional long channel has been changed into a short channel of 0.5 μm or less, a depletion area of the source/drain terminals penetrates into the channel, so that the effective channel length is shortened and the threshold voltage is reduced, resulting in degradation of the gate control function in the MOS transistor, which is called a “short channel effect”.

In order to prevent the short channel effect, one may reduce the thickness of a gate insulating layer, and the channel width between the source and the drain (that is, the maximum width of a depletion area formed below a gate) may be reduced. In addition, it is also advantageous to reduce the impurity density in the semiconductor substrate.

Among other things, a shallow junction in the source/drain terminals is an important factor to be taken into consideration. In this regard, studies and research are being pursued to realize a shallow junction through ion implantation and heat treatment (e.g., annealing and/or dopant activation) processes in the semiconductor manufacturing process.

In addition, most MOS transistors have lightly doped drain (LDD) structures.

The MOS transistor, which is mainly used in digital or mixed signal integrated circuits (e.g., a semiconductor memory device such as a DRAM or SRAM), may be a flat type transistor obtained by forming a conductive layer pattern on a gate insulating layer, after forming the gate insulating layer on a top surface of a silicon substrate.

However, as the semiconductor device has become highly integrated, the line width of the gate pattern is scaled down and the length and width of the channel are reduced, causing the short channel effect (or the narrow channel effect) that CAN deteriorate the performance of the transistor.

In the MOS transistor, the drive current flows through a substrate channel, which is formed below a gate electrode of each cell. However, since the size of the semiconductor device is also scaled down due to the high-integration of the semiconductor device, the drive current may flow through the substrate channel having limited depth and width adjacent to the gate electrode, so that the amount of the drive current is significantly reduced, degrading operational characteristics of the transistor.

In order to solve the above problems related to the short channel effect and the drive current in the MOS transistor, a pin type MOS transistor has been proposed. According to the pin type MOS transistor, a contact area between a substrate and a gate electrode is enlarged while maintaining a shallow junction structure, thereby increasing the drive current.

Hereinafter, description will be made with reference to accompanying drawings to explain a transistor of a semiconductor device according to the related art.

FIG. 1 is a perspective view illustrating a pin type MOS transistor according to the related art, and FIG. 2 is a cross-sectional view of the pin type MOS transistor taken along line I-I of FIG. 1.

As shown in FIGS. 1 and 2, the conventional pin type MOS transistor includes an isolation layer 101 formed on an isolation area of a semiconductor substrate 100, an active area 105 extending in one direction while protruding upward from the top surface of the isolation layer 101 (e.g., from the main body of the semiconductor substrate 100 through the isolation layer 101), a gate electrode 106 extending perpendicularly to the active area 105, which may protrude upward and/or extend in one direction, a gate insulating layer 130 between the gate electrode 106 and the active area 105, and a source/drain impurity area 110 laterally formed on the active area 105 on opposite sides of the gate electrode 106.

Meanwhile, the source/drain impurity areas 110 on the active area 105 are aligned with the gate electrode 106, and a channel area is formed between the source/drain impurity areas 110.

At this time, since the gate electrode 106 extends upward while at least partially surrounding three surfaces of the active area 105 that protrudes upward through the isolation layer 101, the surface area of the gate electrode 106 may increase proportionally to the protrusion degree of the active area 105, as compared with the gate electrode of a flat MOS transistor, so that the amount of the drive current through the channel increases during normal operations.

However, the MOS transistor of the semiconductor device according to the related art exhibits following problems.

As shown in FIG. 2, in the pin type MOS transistor, an edge part 107 of the active area 105 may protrude upward perpendicularly to the main body of the substrate 100 (i.e., at a right angle), so that a part of the gate insulating layer 130 that makes contact with the edge part 107 of the active area 105 may be subject to thinning and/or disconnection.

Also, after the gate insulating layer 130 has been formed, the electric field may concentrate on or at the edge part 107 of the active area 105 having a right-angled configuration, so that the corresponding part of the channel is subject to unpredictable electric field effects, which degrades reliability and/or performance of the semiconductor device. In an extreme case, if the gate insulating layer 130 is sufficiently thin, a sufficiently concentrated electric field at the corner of the channel could cause breakdown of the gate insulating layer 130.

### SUMMARY OF THE INVENTION

The present invention has been made to solve the above problem occurring in the related art, and an object of the present invention is to provide a semiconductor device and a method of fabricating the same, which can prevent disconnection of a gate insulating layer, and/or improve reliability and/or performance of the semiconductor device.

In order to accomplish the above object(s), according to one aspect of the present invention, there is provided a semiconductor device comprising a semiconductor substrate having a protruding active area, which has rounded edge portions; an isolation layer on the semiconductor substrate, on sides of the protruding active area and having an upper surface below an upper surface of the active area; a gate insulating layer and a gate electrode on the active area; and source/drain impurity areas in the active area, adjacent to (opposite) sides of the gate electrode.

According to another aspect of the present invention, there is provided a semiconductor device comprising: an isolation layer on an isolation area of a semiconductor substrate; an active area protruding from the isolation layer in a first direction, in which the active area has a rounded upper portion; a gate insulating layer and a gate electrode on the active area, the gate insulating layer extending in a second direction perpendicular to the first direction; and source/drain impurity areas in the active area adjacent to sides of the gate electrode.

According to still another aspect of the present invention, there is provided a method of fabricating a semiconductor device, comprising removing a part of an isolation layer from a semiconductor substrate such that an active area of the semiconductor substrate protrudes from the isolation layer; rounding edge portions of the active area; forming a gate insulating layer and a gate electrode on the active area; and forming source/drain impurity areas in the active area adjacent to sides of the gate electrode.

### BRIEF DESCRIPTION OF THE DRAWINGS

FIG. 1 is a perspective view illustrating a pin type MOS transistor according to the related art;

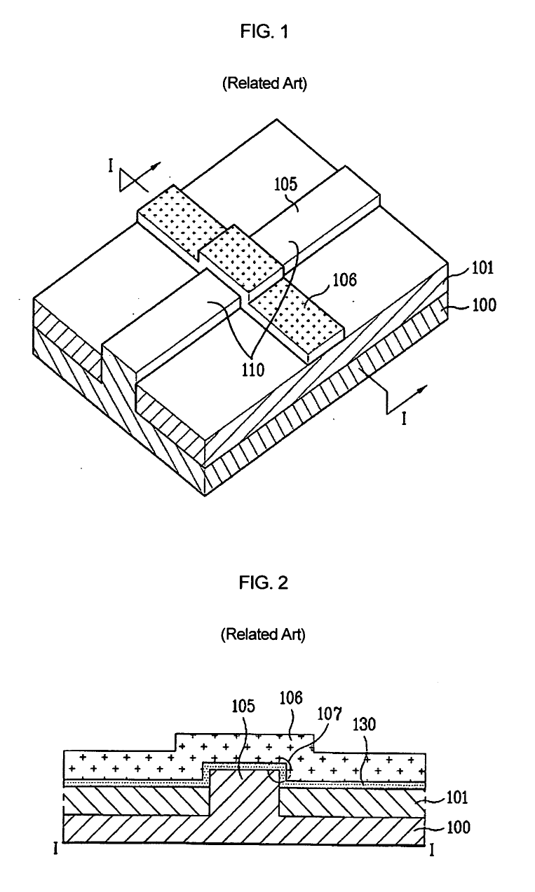

FIG. 2 is a cross-sectional view of a pin type MOS transistor taken along line I-I of FIG. 1;

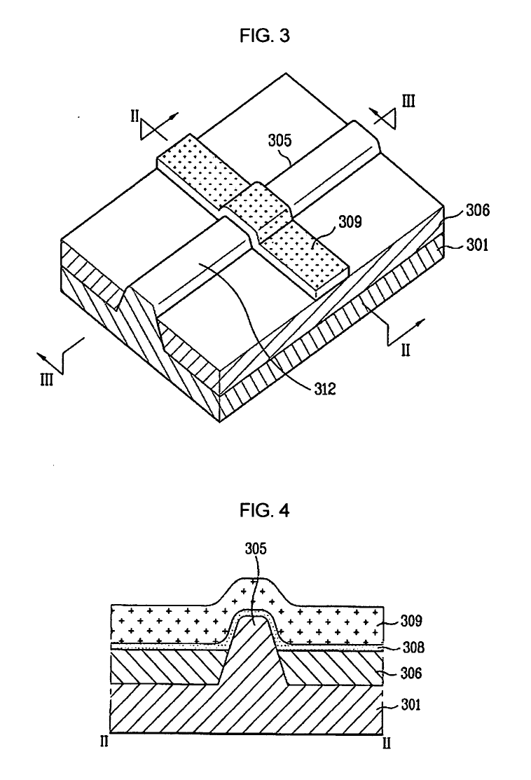

FIG. 3 is a perspective view illustrating a pin type MOS transistor according to an embodiment of the present invention;

FIG. 4 is a cross-sectional view of the illustrative pin type MOS transistor taken along line II-II of FIG. 3;

FIG. 5 is a cross-sectional view of the illustrative pin type MOS transistor taken along line III-III of FIG. 3; and

FIGS. 6A to 6H are cross-sectional views illustrating an exemplary procedure for forming a pin type MOS transistor according to the present invention.

### DETAILED DESCRIPTION OF THE PREFERRED EMBODIMENTS

Hereinafter, a semiconductor device and a method of fabricating the same will be described with reference to accompanying drawings.

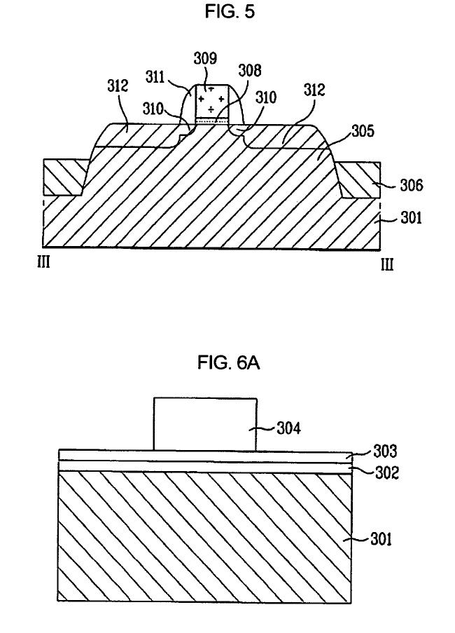

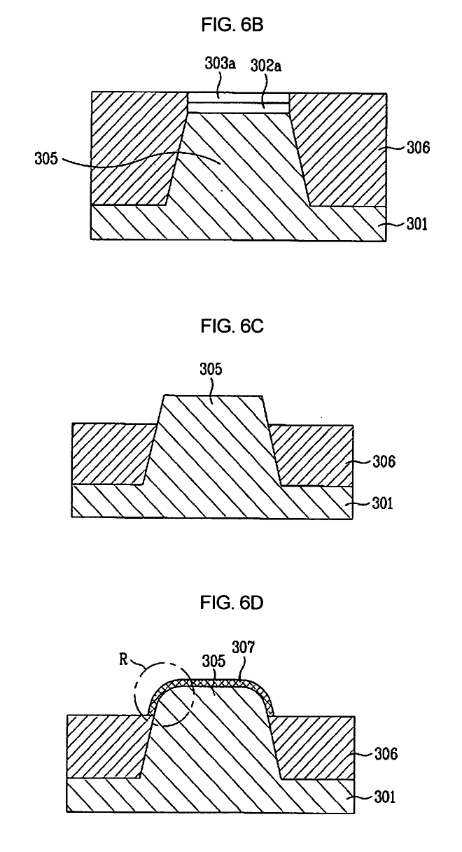

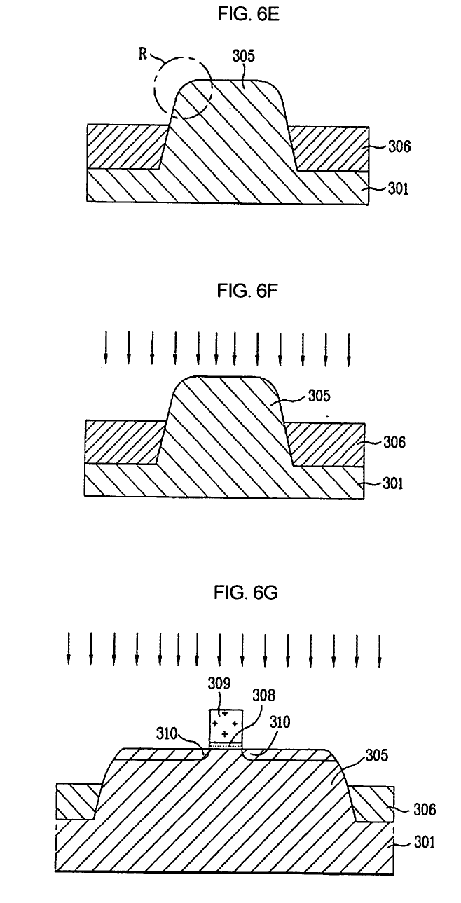

FIG. 3 is a perspective view illustrating a pin type MOS transistor according to an embodiment of the present invention, FIG. 4 is a cross-sectional view of the pin type MOS transistor taken along line II-II of FIG. 3, and FIG. 5 is a cross-sectional view of the pin type MOS transistor taken along line III-III of FIG. 3.

As shown in FIGS. 3 to 5, the pin type MOS transistor of the present invention includes an isolation layer 306 formed on an isolation area of a semiconductor substrate 301, an active area 305 extending in one direction while protruding upward from the top surface of the isolation layer 306 (e.g., through the isolation layer 306) and having rounded edge portions, a gate electrode 309 extending perpendicularly to the active area 305 and a gate insulating layer 308 between gate electrode 309 and the active area 305, sidewall spacers 311 on both sidewalls of the gate electrode 309, LDD areas 310 laterally formed in the active area 305 at opposite sides of the gate electrode 309, and source/drain impurity areas 312 in the active area 305 at opposite sides of the sidewall spacers 311.

The semiconductor substrate 301 generally comprises single crystal silicon, but it may further comprise an epitaxial silicon or silicon-germanium layer grown thereon. The rounded edge portions of the active area 305 are generally along the entire upper surface of the active area 305, although in an alternative embodiment, only the channel region of the active area 305 (i.e., under gate electrode 309 and gate insulating layer 308) have the rounded (upper) edge portions. In another alternative embodiment, the gate insulating layer 308 is only between the gate electrode 309 and active area 305 (i.e., not over the isolation layer 306. In various embodiments, sidewall spacers 311 comprise an oxide (e.g., undoped silicon dioxide), a nitride (e.g., silicon nitride), or a combination thereof (e.g., a nitride-on-oxide bilayer or an oxide-on-nitride-on-oxide trilayer).

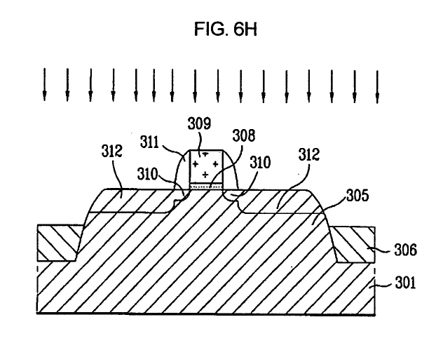

FIGS. 6A to 6H are sectional views illustrating exemplary procedures for forming the pin type MOS transistor according to the present invention.

FIGS. 6A to 6F are sectional views of the pin type MOS transistor taken along line II-II of FIG. 3, and FIGS. 6G and 6H are sectional views of the pin type MOS transistor taken along line III-III of FIG. 3.

First, as shown in FIG. 6A, first and second insulating layers 302 and 303 are sequentially formed on the semiconductor substrate 301. These insulating layers may also be referred to as a buffer layer and a hard mask layer, respectively, to reflect their functions during the formation of the isolation layer.

Herein, the first insulating layer 302 generally includes an oxide layer having a thickness in a range of 20 Å to 100 Å, and the second insulating layer 303 generally includes a nitride layer having a thickness in a range of 500 Å to 1500 Å. The oxide is typically silicon dioxide, which may be thermally grown by conventional wet or dry oxidation or deposited by conventional chemical vapor deposition (CVD). The nitride layer is typically silicon nitride, which may be deposited on the oxide layer 302 by conventional chemical vapor deposition (CVD).

Meanwhile, although the first and second insulating layers 302 and 303 are sequentially formed on the semiconductor substrate 301 according to an embodiment of the present invention, the present invention is not limited to the above embodiment, but a single insulating layer for a hard mask (e.g., comprising silicon nitride or a silicon oxynitride) can be formed.

Then, photoresist 304 is coated on the second insulating layer 303, and then the photoresist 304 is patterned through an exposure and development process, thereby defining the isolation area and the active area.

Here, the active area refers to an area where the photoresist 304 exists, and the isolation area refers to an area where the photoresist 304 has been removed.

After that, as shown in FIG. 6B, the second and first insulating layers 303 and 302 are selectively removed using the patterned photoresist 304 as a mask, thereby forming first and second insulating layer patterns 302a and 303a.

Subsequently, the photoresist 304 is removed, and the isolation area of the semiconductor substrate 301 is selectively removed by conventional dry etching using the first and second insulating layer patterns 302a and 303a as a hard mask, thereby forming a trench having a predetermined depth in the semiconductor substrate 301.

At this time, since the trench is formed in the isolation area of the semiconductor substrate 301, the active area 305 protrudes in one direction (i.e., above the main body of the substrate 301) by a predetermined height. That is, the active area 305 linearly protrudes in one direction. The height may be, for example, from a lower limit of 1000 Å, 1500 Å, or 2000 Å to an upper limit of 5000 Å, 4000 Å, or 3000 Å.

Meanwhile, although the trench may be formed by using the first and second insulating layer patterns 302a and 303a as a mask after removing the photoresist 304, it is also possible to form the trench by etching, also using the photoresist 304 as a mask without removing the photoresist 304. In addition, the trench may be formed with a sloped sidewall as shown in FIGS. 6B-6C. The slope of the trench sidewall (which may be from 80° or 82°, to 86° or 88°, relative to the upper surface of the substrate 301) may be controlled by selecting etchant gases and flow rates providing predetermined carbon, hydrogen and fluorine ratios (e.g., (a C:H:F ratio) that, in turn, can be empirically correlated with a predetermined slope.

Then, a third insulating layer is formed on the entire surface of the semiconductor substrate 301 including the trench, and a CMP (chemical mechanical polishing) process is performed over the whole area of the third insulating layer, thereby forming the isolation layer 306 in the trench. Generally, the third insulating layer comprises an undoped silicon dioxide, formed by conventional CVD. The third insulating layer may further comprise a liner oxide in the trench, formed by conventional thermal oxidation, and a liner nitride thereon (which may be formed by nitridation of the liner oxide at its surface). At this time, the top surface of the second insulating layer pattern 302a may serve as an end point of the CMP process.

After that, as shown in FIG. 6C, the second and first insulating layer patterns 303a and 302a are removed by sequential wet etching processes.

When the second and first insulating layer patterns 303a and 302a are removed by wet etching (especially when the first insulating layer pattern 302a comprises substantially the same material as the isolation layer 306; e.g., silicon dioxide), the top surface of the isolation layer 306 may also be removed by a predetermined thickness and/or to a predetermined depth, so that the active area 305 protrudes from the top surface of the isolation layer 306.

At this time, a phosphoric acid solution is preferably used to remove the second insulating layer pattern 303a (e.g., when it comprises silicon nitride), and the isolation layer 306 can be selectively removed by a predetermined thickness when the first insulating layer pattern 302a is removed, e.g., by wet etching with aqueous HF (preferably dilute [e.g., about 5-16 wt. %] HF in deionized water).

In addition, after removing the second and first insulating layer patterns 303a and 302a, an additional etching process, that is, an etch back process can be performed to remove the top surface of the isolation layer 306 by a predetermined amount or thickness in such a manner that the active area 305 can protrude from the top surface of the isolation layer 306.

Then, as shown in FIG. 6D, the semiconductor substrate 301 is subject to the oxidation process, so that a fourth insulating layer 307 (which may be a sacrificial oxide layer) is formed on the top surface of the active area 305.

Reference character R represents a rounded edge portion of the active area 305, which is rounded during the oxidation process for forming fourth insulating layer 307 on the active area 305 of the semiconductor substrate 301.

In addition, the fourth insulating layer 307 may have a thickness in a range of from 50 Å to 300 Å.

After that, as shown in FIG. 6E, the fourth insulating layer 307 may be removed through a wet etching process, similar to that used to remove the first insulating layer pattern 302a.

Meanwhile, although the present invention has been described in that the fourth insulating layer 307 is formed as a sacrificial oxide layer so as to round the edge portions of the active area 305, the edge portions of the active area 305 can also be rounded by performing a CDE (chemical dry etch) process, preferably having some isotropic etching activity or characteristics.

Then, as shown in FIG. 6F, impurity ions are implanted into the entire surface of the semiconductor substrate 301 through an implantation process to achieve a well implant and to adjust the threshold voltage of the subsequently-formed MOS transistor.

Next, as shown in FIG. 6G, after forming the gate insulating layer 308 on the entire surface of the semiconductor substrate 301 (e.g., by conventional CVD followed by conventional densification by heating at a temperature and for a length of time sufficient to increase the density of the deposited gate insulating layer 308), a conductive layer for a gate electrode is formed on the gate insulating layer 308. Alternatively, gate insulating layer 308 may be thermally grown on the exposed surface(s) of active area 305 to form a relatively high-density silicon dioxide layer. In the latter case, the gate insulating layer 308 is not formed over the isolation layer 306.

Here, it should be noted that FIGS. 6G and 6H are sectional views of the pin type MOS transistor taken along line II-II and III-III of FIG. 3, respectively. Thus, it can be readily understood from FIG. 4 that the edge portions of the active area 305 are rounded, and the gate insulating layer 308 and the conductive layer for the gate electrode are formed on the rounded active area 305.

The gate insulating layer 308 can be obtained through the CVD (chemical vapor deposition) process, the PVD (physical vapor deposition) process, or the ALD (atomic layer deposition) process.

In addition, the conductive layer for the gate electrode includes any one selected from the group consisting of TiN, Ti/TiN, WxNy, and poly-silicon. Alternatively, the gate electrode may includes a plurality of members from the group (e.g., TiN or WₓN_{y} on polysilicon), or a conventional metal silicide (e.g., TiSiₓ, WSiₓ, MoSiₓ, CoSiₓ, NiSiₓ, etc.) on polysilicon.

After that, the conductive layer and the gate insulating layer 308 are patterned (or selectively removed) through photolithography and etching, thereby forming the gate electrode 309 on the active area 305 in the direction perpendicular to the extension direction of the active area 305.

In addition, an n-type or p-type dopant is implanted into the entire surface of the semiconductor substrate 301 (generally at a relatively low density and/or at a relatively low energy) using the gate electrode 309 as a mask, thereby forming the LDD (lightly doped drain) areas 310 on the active area 305 in the lateral direction on opposite sides of the gate electrode 309.

Then, as shown in FIG. 6H, after forming a fifth insulating layer on the entire surface of the semiconductor substrate 301, an etch back (or anisotropic etching) process is performed over the whole area of the fifth insulating layer, thereby forming the sidewall spacers 311 at opposite sidewalls of the gate electrode 309.

Here, the fifth insulating layer may include an oxide layer, a nitride layer, an oxide/nitride layer, a nitride/oxide layer, or an oxide/nitride/oxide layer.

After that, an n-type or p-type dopant is implanted at a high density and at a relatively high energy into the entire surface of the semiconductor substrate 301 using the gate electrode 309 and the sidewall spacers 311 as a mask, thereby forming the source/drain impurity areas 312 in the active area 305 in a lateral direction on opposite sides of the combined gate electrode 309 and the sidewall spacers 311. The same type (n-type or p-type) of dopant is implanted

As described above, the semiconductor device and the method of fabricating the same according to the present invention have various advantages.

For instance, since the edge portion of the protruded active area is rounded, disconnection of the gate insulating layer along the edge portion of the active area can be prevented, so that reliability of the semiconductor devices can be improved. Also, unpredictable electric field effects associated with relatively sharp corners of conductive regions can be reduce or eliminated.

It will be apparent to those skilled in the art that various modifications and variations can be made in the present invention. Thus, it is intended that the present invention covers the modifications and variations thereof within the scope of the appended claims.

What is claimed is:

1. A semiconductor device comprising:
a semiconductor substrate having a protruding active area, which has rounded edge portions;
an isolation layer on the semiconductor substrate, on sides of the protruding active area and having an upper surface below an upper surface of the active area;
a gate insulating layer and a gate electrode on the active area; and
source/drain impurity areas in the active area, adjacent to sides of the gate electrode.

2. The semiconductor device as claimed in claim 1, wherein the active area extends in a first direction, and the gate electrode extends in a second direction.

3. The semiconductor device as claimed in claim 1, wherein the first direction is perpendicular to the second direction.

4. The semiconductor device as claimed in claim 1, wherein the source/drain impurity areas comprise an LDD structure.

5. The semiconductor device as claimed in claim 1, further comprising a sidewall spacer at a sidewall of the gate electrode.

6. A semiconductor device comprising:
an isolation layer on an isolation area of a semiconductor substrate;
an active area protruding from the isolation layer in a first direction, in which the active area has a rounded upper portion;
a gate insulating layer and a gate electrode on the active area, the gate insulating layer extending in a second direction perpendicular to the first direction; and
source/drain impurity areas in the active area adjacent to sides of the gate electrode.

7. The semiconductor device as claimed in claim 6, wherein the source/drain impurity areas comprise an LDD structure.

8. The semiconductor device as claimed in claim 6, further comprising a sidewall spacer at a sidewall of the gate electrode.

9. A method of fabricating a semiconductor device, the method comprising the steps of:
removing a part of an isolation layer from a semiconductor substrate such that an active area of the semiconductor substrate protrudes from the isolation layer;
rounding edge portions of the active area;
forming a gate insulating layer and a gate electrode on the active area; and
forming source/drain impurity areas in the active area adjacent to sides of the gate electrode.

10. The method as claimed in claim 9, further comprising forming the isolation layer in an isolation area of the semiconductor substrate.

11. The method as claimed in claim 10, wherein the step of forming the isolation layer includes the sub-steps of:
forming first and second insulating layers on the semiconductor substrate;
selectively removing portions of the first and second insulating layers to expose the isolation area, thereby forming first and second insulating layer patterns;
selectively removing a portion of the semiconductor substrate using the first and second insulating layer patterns as a mask, thereby forming a trench in the semiconductor substrate; and
forming a third insulating layer in the trench, thereby forming the isolation layer.

12. The method as claimed in claim 9, wherein the step of rounding the edge portions of the active area includes the sub-steps steps of:
forming a sacrificial oxide layer on the active area; and
removing the sacrificial oxide layer.

13. The method as claimed in claim 12, wherein the sub-step of forming the sacrificial oxide layer comprises thermally oxidizing the exposed active area sufficiently to round exposed edge portions of the active area.

14. The method as claimed in claim 9, wherein rounding the edge portions of the active area a chemical dry etch (CDE) process.

15. The method as claimed in claim 11, wherein the first insulating layer includes an oxide layer and the second insulating layer includes a nitride layer.

16. The method as claimed in claim 12, wherein the sacrificial oxide layer has a thickness in a range of from 50 Å to 300 Å.

17. The method as claimed in claim 9, further comprising a step of forming a sidewall spacer at a sidewall of the gate electrode.

18. The method as claimed in claim 9, further comprising a step of forming an LDD area in the active area by ion implantation, using the gate electrode as a mask.

19. The method as claimed in claim 12, wherein removing the sacrificial layer comprises a wet etching process.
